(19) United States
(12) Patent Application Publication
(10) Pub. No.: US 2020/0227530 A1
(43) Pub. Date: Jul. 16, 2020

(54) SEMICONDUCTOR APPARATUS AND METHOD FOR PRODUCING SAME

(71) Applicant: FUJITSU LIMITED, Kawasaki-shi (JP)

(72) Inventors: Yusuke Kumazaki, Atsugi (JP); Kozo Makiyama, Kawasaki (JP); Toshihiro Ohki, Hadano (JP); Shirou OZAKI, Yamato (JP)

(73) Assignee: FUJITSU LIMITED, Kawasaki-shi (JP)

(21) Appl. No.: 16/720,275

(22) Filed: Dec. 19, 2019

(30) Foreign Application Priority Data
Jan. 10, 2019 (JP) 2019-002899

(51) Int. Cl. H01L 29/423; H01L 29/778; H01L 29/205; H01L 29/20; H01L 29/47; H01L 29/40

(52) U.S. Cl. CPC H01L 29/42316; H01L 29/7787; H01L 29/205; H01L 29/402; H01L 29/475; H01L 29/401; H01L 29/2003

(57) ABSTRACT

A semiconductor apparatus includes: a substrate; a first semiconductor layer of a nitride semiconductor disposed over the substrate; a second semiconductor layer of a nitride semiconductor disposed over the first semiconductor layer; an insulating film disposed over the second semiconductor layer; a source electrode and a drain electrode that are disposed over the second semiconductor layer; and a gate electrode. The gate electrode includes: a Schottky region disposed over the second semiconductor layer, and a gate field-plate region disposed over the insulating film in the vicinity of the Schottky region, wherein the gate electrode includes a first gate electrode section disposed in the gate field-plate region so as to face the drain electrode, and a second gate electrode section disposed in the Schottky region, and wherein a material constituting the first gate electrode section has a lower work function than a material constituting the second gate electrode section.

### CROSS-REFERENCE TO RELATED APPLICATION

This application is based upon and claims the benefit of priority of the prior Japanese Patent Application No. 2019-2899, filed on Jan. 10, 2019, the entire contents of which are incorporated herein by reference.

### FIELD

The embodiments discussed herein are related to a semiconductor apparatus and a method for producing the semiconductor apparatus,

### BACKGROUND

Nitride semiconductors, such as GaN, AlN, InN, and mixed crystals thereof have a wide band gap and are used as a material for high-power electronic devices, short-wave light-emitting devices, or the like. Among these, as for high-power electronic devices, technologies concerning field-effect transistors (FETs) and, in particular, high-electron mobility transistors (HEMTs) have been developed (see, for example, Japanese Laid-open Patent Publication No. 2013-157399). HEMTs that include a nitride semiconductor are used in a high-power, high-efficiency amplifier, a high-power switching device, or the like.

One of the FETs that include a nitride semiconductor is a HEMT that includes an electron transit layer composed of GaN and an electron supply layer composed of AlGaN. In the electron transit layer, two-dimensional electron gas (2DEG) is generated due to piezo and spontaneous polarization of GaN. Related technologies are also disclosed in, for example, Japanese Laid-open Patent Publication No. 2016-92397.

Since GaN has a wider band gap than Si or the like, nitride semiconductors are used in applications in which a high voltage is applied to a semiconductor apparatus. There is a demand for a further increase in the withstand voltage of a semiconductor apparatus.

### SUMMARY

According to an aspect of the embodiments, a semiconductor apparatus includes: a substrate; a first semiconductor layer of a nitride semiconductor disposed over the substrate; a second semiconductor layer of a nitride semiconductor disposed over the first semiconductor layer; an insulating film disposed over the second semiconductor layer; a source electrode and a drain electrode that are disposed over the second semiconductor layer; and a gate electrode. The gate electrode includes: a Schottky region disposed over the second semiconductor layer, and a gate field-plate region disposed over the insulating film in the vicinity of the Schottky region, wherein the gate electrode includes a first gate electrode section disposed in the gate field-plate region so as to face the drain electrode, and a second gate electrode section disposed in the Schottky region, and wherein a material constituting the first gate electrode section has a lower work function than a material constituting the second gate electrode section.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram illustrating the structure of a semiconductor apparatus;

FIG. 2 is a diagram illustrating the structure of a semiconductor apparatus that includes a gate field-plate;

FIG. 3 is a diagram used for explaining the semiconductor apparatus illustrated in FIG. 2;

FIG. 4 is a diagram illustrating the structure of a semiconductor apparatus according to a first embodiment;

FIG. 5 is a diagram used for explaining the semiconductor apparatus according to the first embodiment;

FIG. 6 is a diagram illustrating the work functions of metals;

FIG. 7 is a diagram illustrating a step of a method for producing the semiconductor apparatus according to the first embodiment (1);

FIG. 8 is a diagram illustrating a step of the method for producing the semiconductor apparatus according to the first embodiment (2);

FIG. 9 is a diagram illustrating a step of the method for producing the semiconductor apparatus according to the first embodiment (3);

FIG. 10 is a diagram illustrating a step of the method for producing the semiconductor apparatus according to the first embodiment (4);

FIG. 11 is a diagram illustrating a step of the method for producing the semiconductor apparatus according to the first embodiment (5);

FIG. 12 is a diagram illustrating a step of the method for producing the semiconductor apparatus according to the first embodiment (6);

FIG. 13 is a diagram illustrating the structure of a modification example of the semiconductor apparatus according to the first embodiment;

FIG. 14 is a diagram illustrating the structure of a semiconductor apparatus according to a second embodiment;

FIG. 15 is a diagram illustrating a step of a method for producing the semiconductor apparatus according to the second embodiment (1);

FIG. 16 is a diagram illustrating a step of the method for producing the semiconductor apparatus according to the second embodiment (2);

FIG. 17 is a diagram illustrating a step of the method for producing the semiconductor apparatus according to the second embodiment (3);

FIG. 18 is a diagram illustrating a step of the method for producing the semiconductor apparatus according to the second embodiment (4);

FIG. 19 is a diagram illustrating a step of the method for producing the semiconductor apparatus according to the second embodiment (5);

FIG. 20 is a diagram illustrating a step of the method for producing the semiconductor apparatus according to the second embodiment (6);

FIG. 21 is a diagram illustrating the structure of a semiconductor apparatus according to a third embodiment;

FIG. 22 is a diagram illustrating the structure of a semiconductor apparatus according to a fourth embodiment;

FIG. 23 is a diagram used for explaining a discretely packaged semiconductor device according to a fifth embodiment;

FIG. 24 is a circuit diagram of a power supply device according to the fifth embodiment; and

FIG. 25 is a diagram illustrating the structure of a high-frequency amplifier according to the fifth embodiment.

### DESCRIPTION OF EMBODIMENTS

Embodiments are described below. Hereinafter, the same elements and the like are denoted by the same reference numeral, and the description thereof is omitted. The horizontal and vertical scales and the like of the drawings may be changed from the actual one for the sake of simplicity.

### First Embodiment

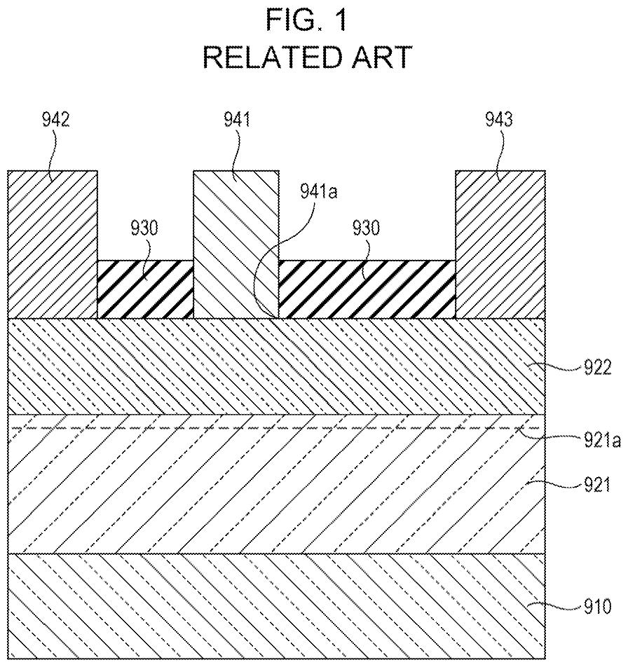

A semiconductor apparatus that includes a nitride semiconductor, that is, for example, a HEMT that includes an electron transit layer composed of GaN and an electron supply layer composed of AlGaN, is described below with reference to FIG. 1. A semiconductor apparatus having the structure illustrated in FIG. 1 includes a substrate 910 and an electron transit layer 921 and an electron supply layer 922 that are stacked over the substrate 910 by epitaxial growth of nitride semiconductors. The substrate 910 is composed of SiC or the like. The electron transit layer 921 is composed of i-GaN. The electron supply layer 922 is composed of AlGaN. As a result, 2DEG 921a is generated in a portion of the electron transit layer 921 which is in the vicinity of the interface between the electron transit layer 921 and the electron supply layer 922. A gate electrode 941, a source electrode 942, and a drain electrode 943 are disposed over the electron supply layer 922. An insulating film 930 is disposed over a portion of the electron supply layer 922 which is exposed at the surface.

In the semiconductor apparatus having the structure illustrated in FIG. 1, a high voltage is applied across the source electrode 942 and the drain electrode 943. The potential applied to the gate electrode 941 is closer to the potential applied to the source electrode 942 than to the potential applied to the drain electrode 943. Consequently, the electric field concentrates at an edge 941a of the gate electrode 941 which faces the drain electrode 943 and may cause a fracture of the semiconductor apparatus.

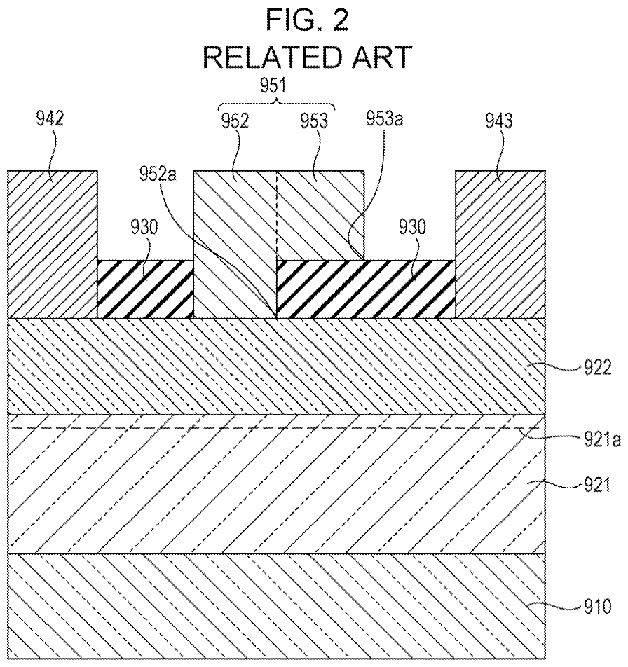

Accordingly, there has been devised a semiconductor apparatus having the structure illustrated in FIG. 2 which includes a gate electrode 951 arranged such that a portion of the gate electrode 951 is disposed over a portion of the insulating film 930 which faces the drain electrode 943 in order to increase the withstand voltage of the semiconductor apparatus. The above structure is referred to as “gate field-plate structure”. The gate electrode 951 of the above structure is constituted by a Schottky region 952 arranged adjacent to the electron supply layer 922 and a gate field-plate region 953 disposed over the insulating film 930 so as to be closer to the drain electrode 943 than the Schottky region 952. The gate electrode 951 having the gate field-plate structure enables the peak of concentration of the electric field to be divided between an edge 952a of the Schottky region 952 which faces the drain electrode 943 and an edge 953a of the gate field-plate region 953 which faces the drain electrode 943. Dividing the peak of concentration of the electric field into two in this manner may reduce the peaks of concentration of the electric field and increase the withstand voltage.

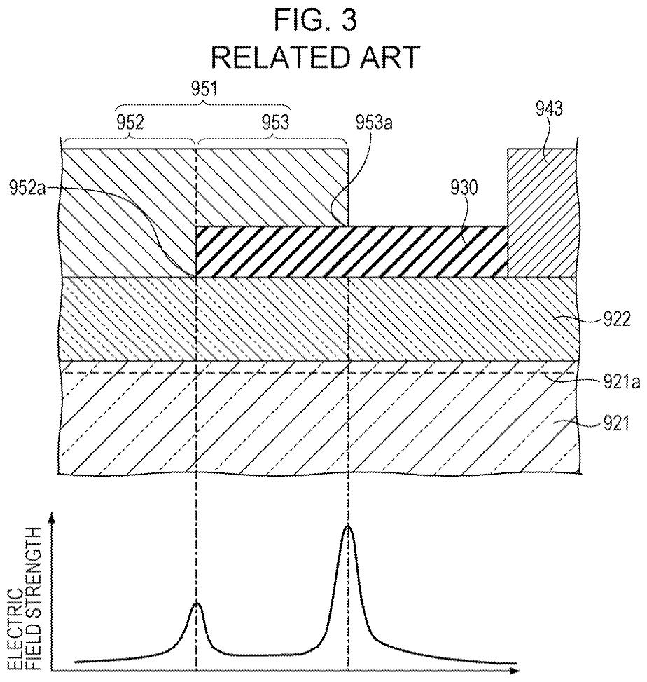

FIG. 3 illustrates the relationship between the structure of the principal part of the semiconductor apparatus illustrated in FIG. 2 and electric field strength. As illustrated in FIG. 3, the peaks of concentration of the electric field occur at the edge 952a of the Schottky region 952 of the gate electrode 951 which faces the drain electrode 943 and the edge 953a of the gate field-plate region 953 of the gate electrode 951 which faces the drain electrode 943. Accordingly, the gate field-plate region 953 may reduce the strength of the electric field at the edge 952a of the Schottky region 952 which faces the drain electrode 943 and increase the withstand voltage.

However, if the strength of the electric field is high at the edge 953a of the gate field-plate region 953 which faces the drain electrode 943, a fracture or the like may occur at the edge 953a. Therefore, a semiconductor apparatus having a further high withstand voltage is anticipated.

(Semiconductor Apparatus)

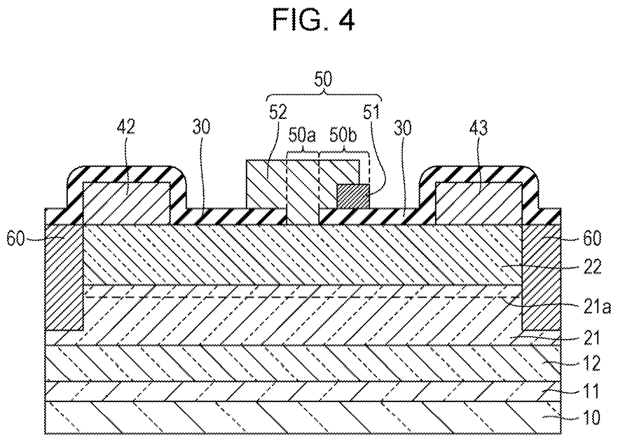

A semiconductor apparatus according to a first embodiment is described below with reference to FIG. 4. The semiconductor apparatus according to the first embodiment includes a substrate 10 and a nucleation layer 11, a buffer layer 12, an electron transit layer 21, and an electron supply layer 22 that are stacked over the substrate 10 by epitaxial growth of nitride semiconductors. The substrate 10 is composed of SiC or the like and may alternatively be composed of Si, sapphire, GaN, AlN, diamond, or the like. The nucleation layer 11 is composed of AlN or the like. The buffer layer 12 is composed of AlN, GaN, or the like. The electron transit layer 21 is composed of i-GaN. The electron supply layer 22 is composed of InAlN. As a result, 2DEG 21a is generated in a portion of the electron transit layer 21 which is in the vicinity of the interface between the electron transit layer 21 and the electron supply layer 22. An element separation region 60 is formed in the nitride semiconductor layers. Hereinafter, the electron transit layer 21 may be referred to as “first semiconductor layer”, and the electron supply layer 22 may be referred to as “second semiconductor layer”.

A gate electrode 50, a source electrode 42, and a drain electrode 43 are disposed over the electron supply layer 22. An insulating film 30 is disposed over the electron supply layer 22 so as to cover the exposed surface of the electron supply layer 22. The insulating film 30 is composed of silicon nitride (SiN) and may alternatively be composed of an oxide, a nitride, or an oxynitride of Si, Al, Hf, Zr, Ta, or the like.

In the first embodiment, the gate electrode 50 includes a first gate electrode section 51 and a second gate electrode section 52. The gate electrode 50 is constituted by a Schottky region 50a arranged adjacent to the electron supply layer 22, a gate field-plate region 50b disposed over the insulating film 30 so as to be closer to the drain electrode 43 than the Schottky region 50a and a region over the insulating film 30 closer to the source electrode 42 than the Schottky region 50a. The first gate electrode section 51 is disposed over the insulating film 30 in a part of the gate field-plate region 50b of the gate electrode 50 which faces the drain electrode 43. In the gate field-plate region 50b, the second gate electrode section 52 is disposed over the first gate electrode section 51 and also over a portion of the insulating film 30 so as to be closer to the Schottky region 50a than the first gate electrode section 51.

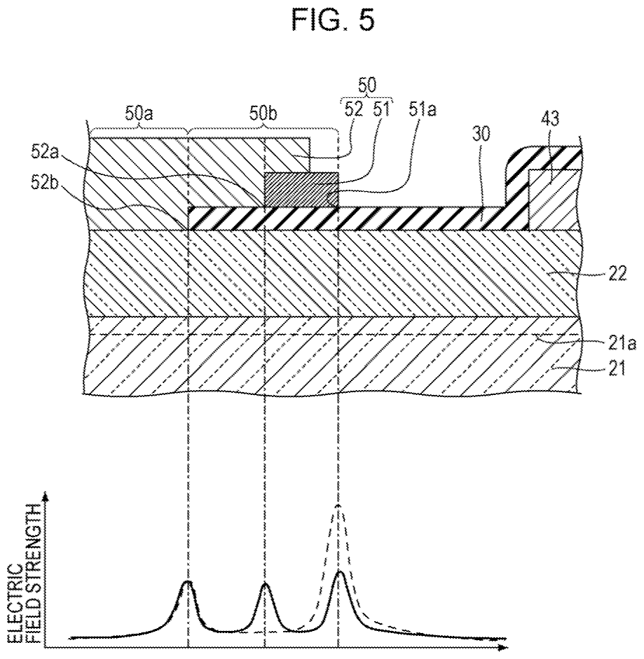

The first gate electrode section 51 is composed of a material having a lower work function than the material constituting the second gate electrode section 52. This enables the peak of concentration of the electric field to be divided into three as illustrated in FIG. 5 and may increase the withstand voltage. FIG. 5 illustrates the relationship between the structure of the principal part of the semiconductor apparatus according to the first embodiment and electric field strength. In the distribution of electric field strength illustrated in FIG. 5, the broken line denotes the distribution of strength of the electric field generated in the semiconductor apparatus having the structure illustrated in FIG. 3, and the solid line denotes the distribution of strength of the electric field generated in the semiconductor apparatus according to the first embodiment.

As illustrated in FIG. 5, in the gate field-plate region 50b, the peak of concentration of the electric field may be divided between an edge 51a of the first gate electrode section 51 which faces the drain electrode 43 and an edge 52a of the second gate electrode section 52 which faces the drain electrode 43. A peak of concentration of the electric field also occurs in the Schottky region 50a at an edge 52b of the second gate electrode section 52 which faces the drain electrode 43. Dividing the peak of concentration of the electric field into three in this manner may reduce the peaks of concentration of the electric field and increase the withstand voltage.

That is, in the gate field-plate region 50b, a peak of concentration of the electric field is caused to occur at the edge 52a of the second gate electrode section 52 which faces the drain electrode 43 in order to reduce the peak of concentration of the electric field that occurs at the edge 51a of the first gate electrode section 51 which faces the drain electrode 43. This may reduce the peaks of concentration of the electric field and increase the withstand voltage.

In the first embodiment, the work function of the material constituting the first gate electrode section 51 is less than 5.0 eV and is preferably 4.5 eV or less. The work function of the material constituting the second gate electrode section 52 is preferably 5.0 eV or more.

The difference in work function between the material constituting the first gate electrode section 51 and the material constituting the second gate electrode section 52 is preferably 0.5 eV or more and is more preferably 1.0 eV or more. When the difference in work function between the material constituting the first gate electrode section 51 and the material constituting the second gate electrode section 52 is large, the strength of the electric field that occurs at the edge 52a of the second gate electrode section 52 which faces the drain electrode 43 is increased. This may reduce the strength of the electric field that occurs at the edge 51a of the first gate electrode section 51 which faces the drain electrode 43 accordingly and increase the withstand voltage.

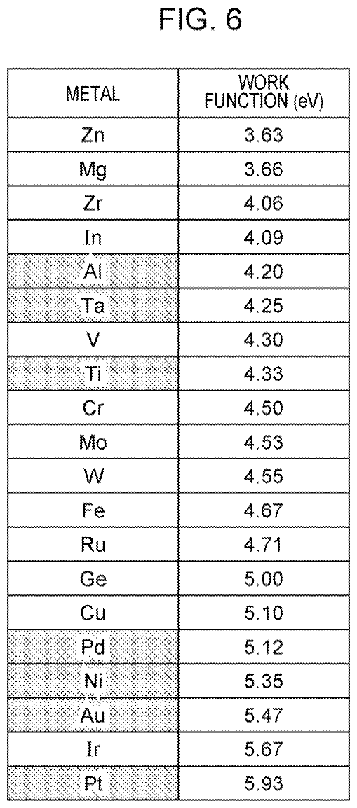

FIG. 6 illustrates the work functions of metal elements. The first gate electrode section 51 may be composed of an element having a work function of less than 5.0 eV. Specific examples of the element include Zn, Mg, Zr, In, Al, Ta, V, Ti, Cr, Mo, W, Fe, and Ru. It is more preferable that the first gate electrode section 51 be composed of an element having a work function of 4.5 eV or less. Specific examples of the element include Zn, Mg, Zr, In, Al, Ta, V, Ti, and Cr. The second gate electrode section 52 may be composed of an element having a work function of 5.0 eV or more. Specific examples of the element include Pt, Ir, Au, Ni, Pd, Cu, and Ge.

From the viewpoint of practicality, the first gate electrode section 51 is preferably composed of Al, Ta, or Ti, and the second gate electrode section 52 is preferably composed of Pt, Au, Ni, or Pd. For example, in the case where the first gate electrode section 51 is composed of Ti and the second gate electrode section 52 is composed of Ni, the difference in work function is 1.02 eV, that is, 1 eV or more. In the case where the first gate electrode section 51 is composed of Al and the second gate electrode section 52 is composed of Pt, the difference in work function is 1.73 eV.

(Method for Producing Semiconductor Apparatus)

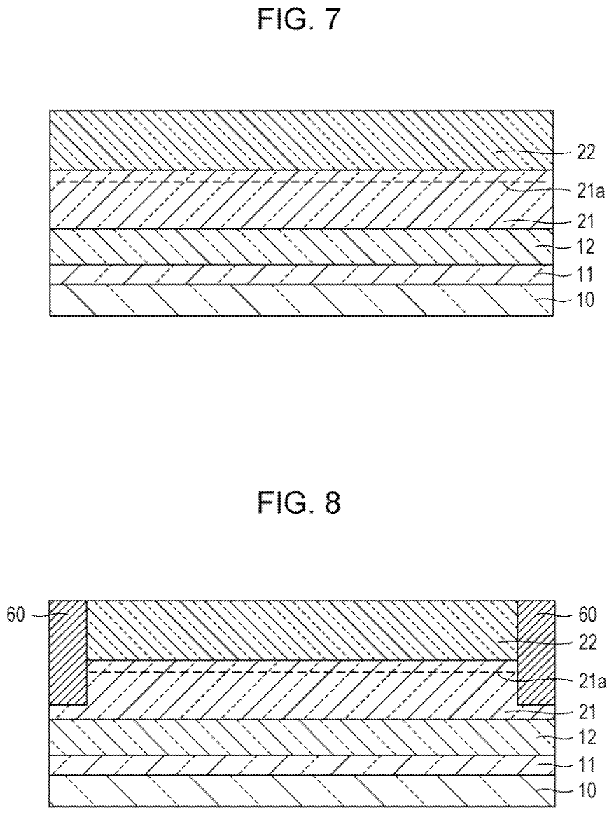

A method for producing the semiconductor apparatus according to the first embodiment is described below with reference to FIGS. 7 to 12.

As illustrated in FIG. 7, nitride semiconductor layers are epitaxially grown over a substrate 10 to form a nucleation layer 11, a buffer layer 12, an electron transit layer 21, and an electron supply layer 22. As a result, 2DEG 21a is generated in a portion of the electron transit layer 21 which is in the vicinity of the interface between the electron transit layer 21 and the electron supply layer 22. The epitaxial growth of the nitride semiconductor layers is performed using metal organic vapor phase epitaxy (MOVPE).

Although the substrate 10 used in the first embodiment is a SIC substrate, the substrate 10 may be a sapphire substrate, a Si substrate, a SIC substrate, or a GaN substrate. The nucleation layer 11 is composed of AlN or the like. The buffer layer 12 is composed of AlGaN or the like. The electron transit layer 21 is composed of i-GaN having a thickness of 3 μm. The electron supply layer 22 is composed of InAlN having a thickness of 6 nm. The electron supply layer 22 may alternatively be composed of InAlGaN.

As illustrated in FIG. 8, element separation regions 60, which separate elements from one another, are formed in the nitride semiconductor layers. For example, a photoresist is applied onto the electron supply layer 22, and the resulting coating film is exposed to light with an exposure device and developed into a resist pattern (not illustrated) having openings corresponding to the positions at which the element separation regions 60 are to be formed. Argon (Ar) ions are injected into the portions of the nitride semiconductor layers over which the resist pattern is not disposed to form the element separation regions 60. The element separation regions 60 may alternatively be formed by partially removing the portions of the nitride semiconductor layers over which the resist pattern is not disposed by dry etching, such as reactive ion etching (RIE) with a chlorine-containing gas. The portions removed by dry etching are to be filled with an insulating film. The resist pattern is removed using an organic solvent or the like subsequent to the formation of the element separation regions 60.

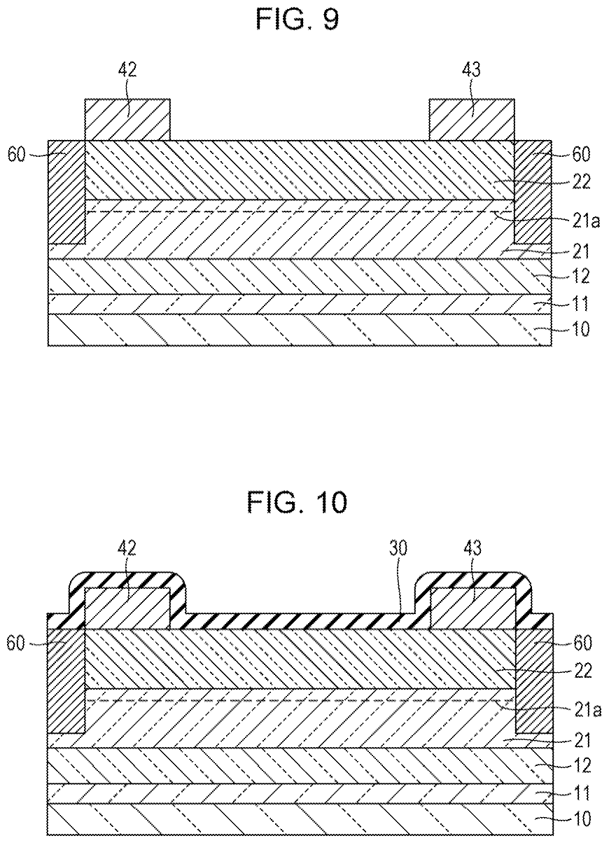

As illustrated in FIG. 9, a source electrode 42 and a drain electrode 43 are formed over the electron supply layer 22. For example, a photoresist is applied onto the electron supply layer 22 and so on. The resulting coating film is exposed to light with an exposure device and developed into a resist pattern (not illustrated) having openings that correspond to the positions at which the source electrode 42 and the drain electrode 43 are to be formed. Subsequent to the formation of the resist pattern, a metal multilayer film composed of Ti/Al is formed over the resist pattern by vacuum vapor deposition and then immersed in an organic solvent to remove the resist pattern and a portion of the metal multilayer film which is disposed over the resist pattern by lift-off. The other portions of the metal multilayer film which remain over the electron supply layer 22 form a source electrode 42 and a drain electrode 43. The metal multilayer film composed of Ti/Al is a multilayer film consisting of a Ti film having a thickness of 2 to 50 nm and an Al film having a thickness of 100 to 300 nm and is formed such that the Ti film comes into contact with the electron supply layer 22 and so on. Subsequently, a heat treatment is performed in a nitrogen atmosphere at a temperature of 500° C. to 900° C., that is, for example, about 600° C., to establish an ohmic contact at the source electrode 42 and the drain electrode 43.

As illustrated in FIG. 10, an insulating film 30 that is a passivation film is formed over the electron supply layer 22 and so on by plasma chemical vapor deposition (CVD). The insulating film 30 is composed of SiN or the like and has a thickness of 2 to 1000 nm, that is, for example, 100 nm. For forming the insulating film 30, atomic layer deposition (ALD) and sputtering may be used alternatively. The insulating film 30 may alternatively be composed of an oxide, a nitride, or an oxynitride of Si, Al, Hf, Zr, Ta, or the like instead of SiN.

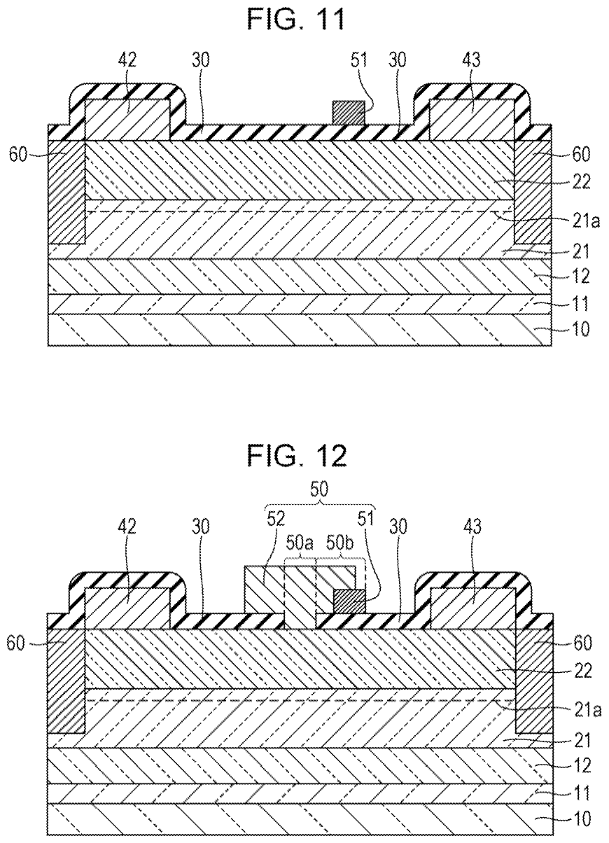

As illustrated in FIG. 11, a first gate electrode section 51 is formed over the insulating film 30. The first gate electrode section 51 is formed in a part of the gate field-plate region 50b of the gate electrode 50 which faces the drain electrode 43. For example, a photoresist is applied onto the insulating film 30. The resulting coating film is exposed to light with an exposure device and developed into a resist pattern (not illustrated) having an opening that corresponds to the position at which the first gate electrode section 51 is to be formed. Subsequent to the formation of the resist pattern, a Ti film is formed over the resist pattern by vacuum vapor deposition and then immersed in an organic solvent to remove the resist pattern and a portion of the Ti film which is disposed over the resist pattern by lift-off. The remaining portion of the Ti film forms a first gate electrode section 51 over the insulating film 30. The first gate electrode section 51 is disposed in a part of the gate field-plate region 50b of the gate electrode 50 which faces the drain electrode 43.

As illustrated in FIG. 12, a second gate electrode section 52 is formed. The first gate electrode section 51 and the second gate electrode section 52 form a gate electrode 50. For example, a photoresist is applied onto the insulating film 30 and the first gate electrode section 51. The resulting coating film is exposed to light with an exposure device and developed into a resist pattern (not illustrated) having an opening that corresponds to the position at which the Schottky region 50a of the gate electrode 50 is to be formed. A portion of the insulating film 30 which is exposed through the opening of the resist pattern is removed by dry etching, such as RIE with a fluorine-containing gas, to form an opening in the insulating film 30 through which the electron supply layer 22 is exposed. The resist pattern is removed using an organic solvent or the like. Then, a photoresist is applied onto the first gate electrode section 51, the insulating film 30, and the electron supply layer 22. The resulting coating film is exposed to light with an exposure device and developed into a resist pattern (not illustrated) having an opening that corresponds to the position at which the second gate electrode section 52 is to be formed. Subsequent to the formation of the resist pattern, a Au film is formed over the resist pattern by vacuum vapor deposition and then immersed in an organic solvent to remove the resist pattern and a portion of the Au film which is disposed over the resist pattern by lift-off. The remaining portion of the Au film forms a second gate electrode section 52. The first gate electrode section 51 and the second gate electrode section 52 form a gate electrode 50. Thus, the first gate electrode section 51 is disposed in a part of the gate field-plate region 50b of the gate electrode 50 which faces the drain electrode 43. The second gate electrode section 52 is disposed in the Schottky region 50a disposed over the electron supply layer 22, over the first gate electrode section 51 disposed in the gate field-plate region 50b, and over a portion of the insulating film 30 which is closer to the Schottky region 50a than the first gate electrode section 51.

The semiconductor apparatus according to the first embodiment may be produced through the above-described steps.

### MODIFICATION EXAMPLE

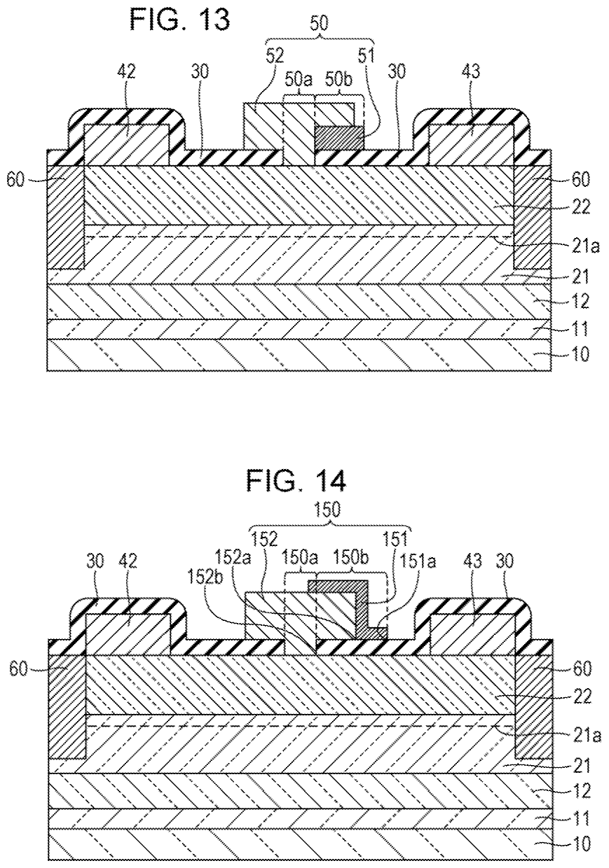

In the semiconductor apparatus according to the first embodiment, as illustrated in FIG. 13, the first gate electrode section 51 may be formed all over the gate field-plate region 50b of the gate electrode 50 which faces the drain electrode 43. In such a case, although the number of the peaks of concentration of the electric field is reduced to two, the withstand voltage may be increased compared with a semiconductor apparatus having the structure illustrated in FIG. 2 by forming the portion of the gate field-plate region 50b which faces the drain electrode 43 using a material having a lower work function than the material constituting the Schottky region 50a. For further increasing the withstand voltage, it is preferable to form both first gate electrode section 51 and second gate electrode section 52 in the gate field-plate region 50b of the gate electrode 50 which faces the drain electrode 43 as illustrated in FIG. 4 and the like.

### Second Embodiment

A semiconductor apparatus according to a second embodiment is described below with reference to FIG. 14. The semiconductor apparatus according to the second embodiment includes a gate electrode 150 including a first gate electrode section 151 and a second gate electrode section 152. The gate electrode 150 is constituted by a Schottky region 150a, a gate field-plate region 150b and a region over the insulating film 30 closer to the source electrode 42 than the Schottky region 150a. The first gate electrode section 151 covers a portion of the second gate electrode section 152 in the gate field-plate region 150b and is disposed over a portion of the insulating film 30 which is closer to the drain electrode 43 than the second gate electrode section 152. In the second embodiment, the peak of concentration of the electric field may be divided into three as in the first embodiment. That is, the peak of concentration of the electric field may be divided among an edge 151a of the first gate electrode section 151 which faces the drain electrode 43, an edge 152a of the gate field-plate region 150b of the second gate electrode section 152 which faces the drain electrode 43, and an edge 152b of the Schottky region 150a. The material constituting the second gate electrode section 152 has a higher work function than the material constituting the first gate electrode section 151 as in the first embodiment.

(Method for Producing Semiconductor Apparatus)

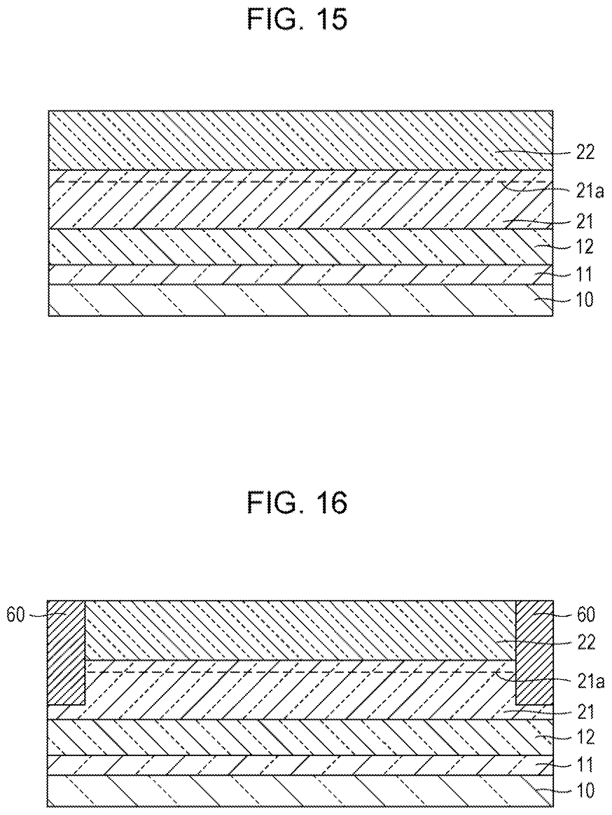

A method for producing the semiconductor apparatus according to the second embodiment is described below with reference to FIGS. 15 to 20.

As illustrated in FIG. 15, nitride semiconductor layers are epitaxially grown over a substrate 10 to form a nucleation layer 11, a buffer layer 12, an electron transit layer 21, and an electron supply layer 22. As a result, 2DEG 21a is generated in a portion of the electron transit layer 21 which is in the vicinity of the interface between the electron transit layer 21 and the electron supply layer 22. The epitaxial growth of the nitride semiconductor layers is performed using MOVPE.

As illustrated in FIG. 16, element separation regions 60, which separate elements from one another, are formed in the nitride semiconductor layers.

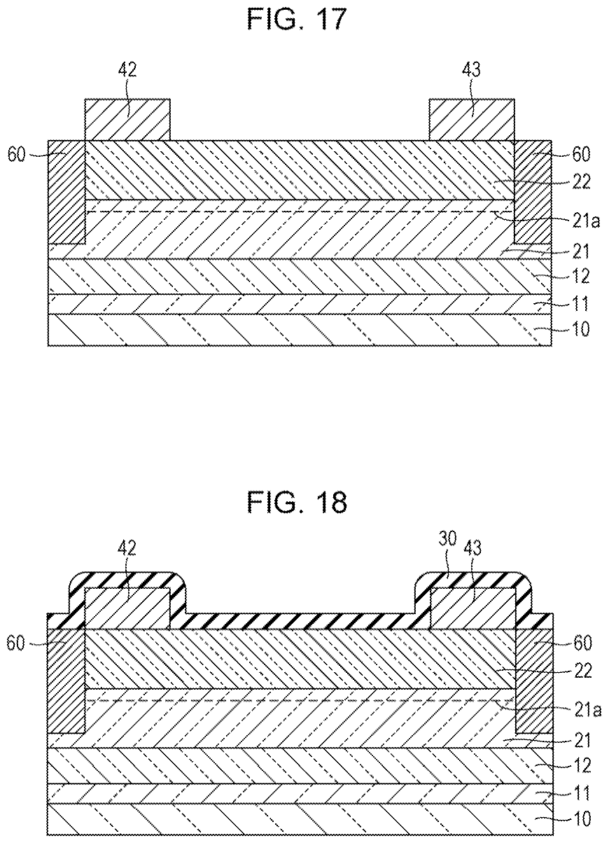

As illustrated in FIG. 17, a source electrode 42 and a drain electrode 43 are formed over the electron supply layer 22.

As illustrated in FIG. 18, an insulating film 30 that is a passivation film is formed over the electron supply layer 22 and so on by plasma CVD.

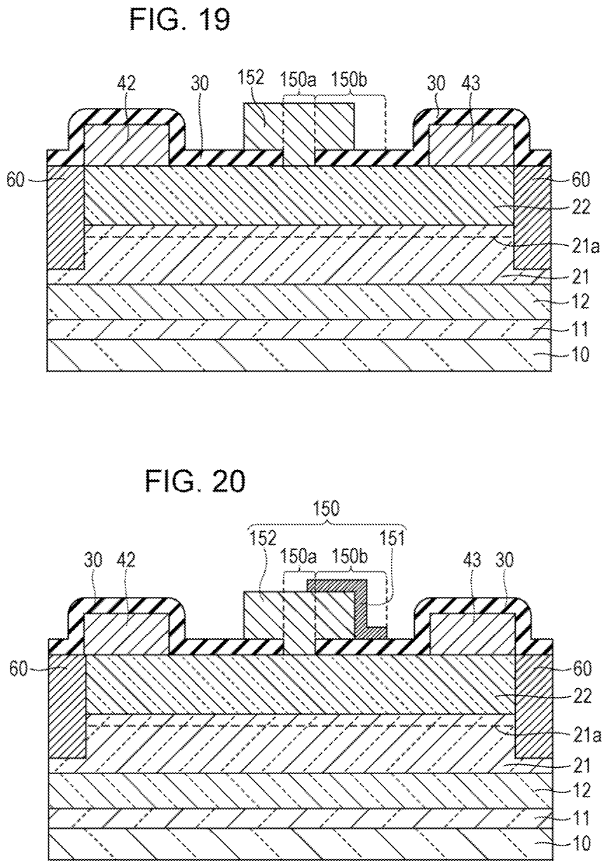

As illustrated in FIG. 19, a second gate electrode section 152 is formed in the Schottky region 150a disposed over the electron supply layer 22 and over a portion of the insulating film 30 which is in the vicinity of the Schottky region 150a in a part of the gate field-plate region 150b. For example, a photoresist is applied onto the insulating film 30. The resulting coating film is exposed to light with an exposure device and developed into a resist pattern (not illustrated) having an opening that corresponds to the position at which the Schottky region 150a of the gate electrode 150 is to be formed. A portion of the insulating film 30 which is exposed through the opening of the resist pattern is removed by dry etching, such as RIE with a fluorine-containing gas, to form an opening in the insulating film 30 through which the electron supply layer 22 is exposed. The resist pattern is removed using an organic solvent or the like. Then, a photoresist is applied onto the insulating film 30 and the electron supply layer 22. The resulting coating film is exposed to light with an exposure device and developed into a resist pattern (not illustrated) having an opening that corresponds to the position at which the second gate electrode section 152 is to be formed. Subsequent to the formation of the resist pattern, a Au film is formed over the resist pattern by vacuum vapor deposition and then immersed in an organic solvent to remove the resist pattern and a portion of the Au film which is disposed over the resist pattern by lift-off. The remaining portion of the Au film forms a second gate electrode section 152 in the Schottky region 150a disposed over the electron supply layer 22 and in a part of the gate field-plate region 150b which is in the vicinity of the Schottky region 150a.

As illustrated in FIG. 20, a first gate electrode section 151 is formed over a portion of the insulating film 30 which is closer to the drain electrode 43 than the second gate electrode section 152. For example, a photoresist is applied onto the insulating film 30 and the second gate electrode section 152. The resulting coating film is exposed to light with an exposure device and developed into a resist pattern (not illustrated) having an opening that corresponds to the position at which the first gate electrode section 151 is to be formed. Subsequent to the formation of the resist pattern, a Ti film is formed over the resist pattern by vacuum vapor deposition and then immersed in an organic solvent to remove the resist pattern and a portion of the Ti film which is disposed over the resist pattern by lift-off. The remaining portion of the Ti film forms a first gate electrode section 151 over the insulating film 30 in a part of the gate field-plate region 150b of the gate electrode 150 which faces the drain electrode 43. The first gate electrode section 151 may cover a portion of the second gate electrode section 152. The first gate electrode section 151 and the second gate electrode section 152 form a gate electrode 150 in the above-described manner. Thus, the first gate electrode section 151 is disposed in a part of the gate field-plate region 150b of the gate electrode 150 which faces the drain electrode 43. The second gate electrode section 152 is disposed in the Schottky region 150a disposed over the electron supply layer 22 and over a portion of the insulating film 30 which is closer to the Schottky region 150a than the first gate electrode section 151 in the gate field-plate region 150b.

The semiconductor apparatus according to the first embodiment may be produced through the above-described steps.

Elements other than those described above are the same as in the first embodiment.

### Third Embodiment

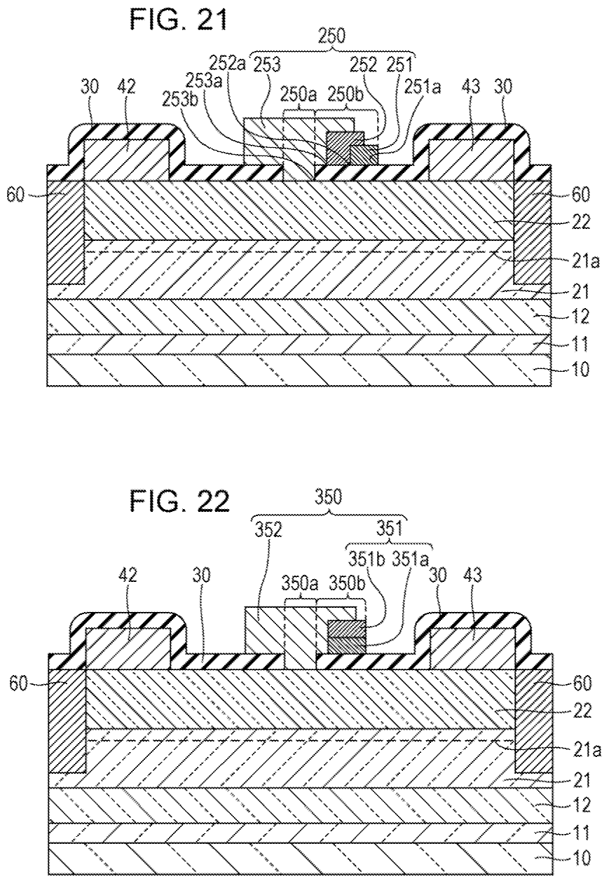

A semiconductor apparatus according to a third embodiment is described below with reference to FIG. 21. The semiconductor apparatus according to the third embodiment includes a gate electrode 250 including a first gate electrode section 251, a second gate electrode section 252, and a third gate electrode section 253. The gate electrode 250 is constituted by a Schottky region 250a arranged adjacent to the electron supply layer 22, a gate field-plate region 250b disposed over the insulating film 30 so as to be closer to the drain electrode 43 than the Schottky region 250a and a region over the insulating film 30 closer to the source electrode 42 than the Schottky region 250a.

The first gate electrode section 251 is disposed over the insulating film 30 in a part of the gate field-plate region 250b of the gate electrode 250 which is closest to the drain electrode 43. The second gate electrode section 252 is disposed in a part of the gate field-plate region 250b of the gate electrode 250 which is closer to the Schottky region 250a than the first gate electrode section 251. The third gate electrode section 253 is disposed in the Schottky region 250a, over a portion of the insulating film 30 which is closer to the Schottky region 250a than the second gate electrode section 252, and over the second gate electrode section 252 in the gate field-plate region 250b.

The material constituting the first gate electrode section 251 has a lower work function than the material constituting the second gate electrode section 252. The material constituting the second gate electrode section 252 has a lower work function than the material constituting the third gate electrode section 253. This enables the peak of concentration of the electric field to be divided into four and may increase the withstand voltage.

In the semiconductor apparatus illustrated in FIG. 21, the number of peaks of concentration of the electric field which may occur in the gate field-plate region 250b is three. That is, the peak of concentration of the electric field may be divided into multiple portions. For example, the peak of concentration of the electric field may be divided among an edge 251a of the first gate electrode section 251 which faces the drain electrode 43, an edge 252a of the second gate electrode section 252 which faces the drain electrode 43, and an edge 253a of the third gate electrode section 253 which faces the drain electrode 43, which are disposed over the insulating film 30. A peak of concentration of the electric field also occurs at an edge 253b of the Schottky region 250a of the third gate electrode section 253 which faces the drain electrode 43. That is, the peak of concentration of the electric field may be divided into four. In the third embodiment, for example, the first gate electrode section 251 is composed of Al, the second gate electrode section 252 is composed of W, and the third gate electrode section 253 is composed of Au.

This enables a reduction in the peaks of concentration of he electric field and may further increase the withstand voltage.

Elements other than those described above are the same as in the first embodiment The third embodiment may be applied to the second embodiment. cl Fourth Embodiment

A semiconductor apparatus according to a fourth embodiment is described below with reference to FIG. 22. The semiconductor apparatus according to the fourth embodiment includes a gate electrode 350 that includes a first gate electrode section 351 and a second gate electrode section 352. The gate electrode 350 is constituted by a Schottky region 350a arranged adjacent to the electron supply layer 22, a gate field-plate region 350b disposed over the insulating film 30 so as to be closer to the drain electrode 43 than the Schottky region 350a and a region over the insulating film 30 closer to the source electrode 42 than the Schottky region 350a. The first gate electrode section 351 is disposed over the insulating film 30 in a part of the gate field-plate region 350b of the gate electrode 350 which faces the drain electrode 43. In the gate field-plate region 350b, the second gate electrode section 352 is disposed over the first gate electrode section 351 and over a portion of the insulating film 30 which is closer to the Schottky region 350a than the first gate electrode section 351.

The first gate electrode section 351 is constituted by a first layer 351a arranged to come into contact with the insulating film 30 and a second layer 351b disposed over the first layer 351a. The material constituting the first layer 351a of the first gate electrode section 351 has a lower work function than the material constituting the second gate electrode section 352. Since the first layer 351a of the first gate electrode section 351 is covered with the second layer 351b in the fourth embodiment, the material constituting the first layer 351a may be selected from the materials that are not commonly used for producing an electrode for semiconductor apparatuses because they are prone to oxidation and the like in spite of having a low work function.

For example, the first layer 351a of the first gate electrode section 351 may be composed of Zn, the second layer 351b of the first gate electrode section 351 may be composed of Au, and the second gate electrode section 352 may be composed of Pt. In such a case, the difference in work function between the material constituting the first layer 351a of the first gate electrode section 351 and the material constituting the second gate electrode section 352 is 2.30 eV.

Elements other than those described above are the same as in the first embodiment.

### Fifth Embodiment

A fifth embodiment is described below. The fifth embodiment relates to a semiconductor device, a power supply device, and a high-frequency amplifier.

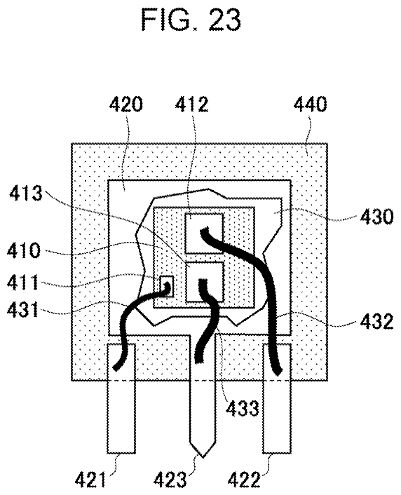

The semiconductor device according to the fifth embodiment is produced by discretely packaging the semiconductor apparatus according to any one of the first to fourth embodiments. The discretely packaged semiconductor device is described with reference to FIG. 23. FIG. 23 schematically illustrates the inside of a discretely packaged semiconductor apparatus; the positions and so on of the electrodes illustrated in FIG. 23 are different from those described in the first to fourth embodiments.

The semiconductor apparatus according to any one of the first to fourth embodiments is cut, by dicing or the like, into a semiconductor chip 410 that is, for example, a HEMT including GaN semiconductor materials. The semiconductor chip 410 is fixed to a lead frame 420 with a die-attach material 430, such as solder. The semiconductor chip 410 corresponds to the semiconductor apparatus according to any one of the first to fourth embodiments.

A gate electrode 411 is coupled to a gate lead 421 with a bonding wire 431. A source electrode 412 is coupled to a source lead 422 with a bonding wire 432. A drain electrode 413 is coupled to a drain lead 423 with a bonding wire 433. The bonding wires 431, 432, and 433 are made of a metal, such as Al. In the fifth embodiment, the gate electrode 411 is a gate electrode pad and is coupled to any one of the gate electrodes 50, 150, 250, and 350 of the semiconductor apparatuses according to the first to fourth embodiments. The source electrode 412 is a source electrode pad and is coupled to the source electrode 42 of the semiconductor apparatus according to any one of the first to fourth embodiments. The drain electrode 413 is a drain electrode pad and is coupled to the drain electrode 43 of the semiconductor apparatus according to any one of the first to fourth embodiments.

Subsequently, resin sealing is performed with a mold resin 440 by transfer molding. Hereby, a discretely packaged semiconductor device, such as a HEMT including GaN semiconductor materials, may be produced.

The power supply device and high-frequency amplifier according to the fifth embodiment are described below. The power supply device and high-frequency amplifier according to the fifth embodiment include the semiconductor apparatus according to any one of the first to fourth embodiments.

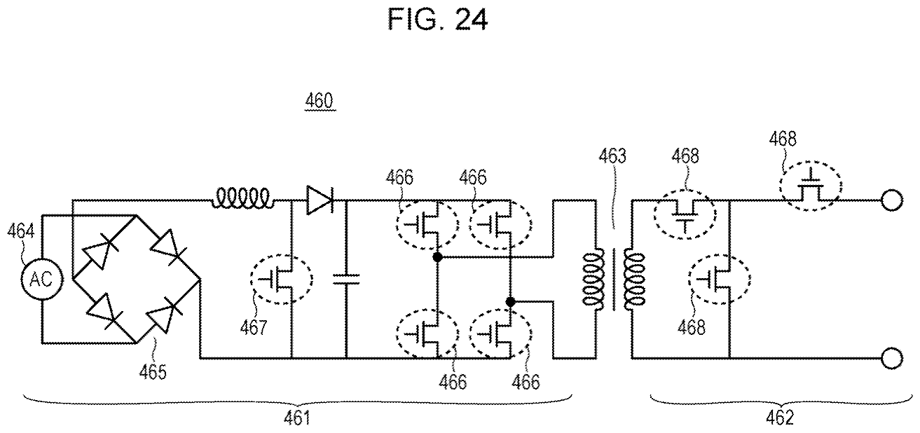

The power supply device according to the fifth embodiment described below with reference to FIG. 24. A power supply device 460 according to the fifth embodiment includes a high-voltage primary circuit 461, a low-voltage secondary circuit 462, and a transformer 463 interposed between the primary circuit 461 and the secondary circuit 462. The primary circuit 461 includes an AC power source 464, a “bridge rectifier” 465, a plurality of switching elements 466 (four in the power supply device illustrated in FIG. 24), and one switching element 467. The secondary circuit 462 includes a plurality of switching elements 468 (three in the power supply device illustrated in FIG. 24). The power supply device illustrated in FIG. 24 includes the semiconductor apparatuses according to any one of the first to fourth embodiments, which serve as the switching elements 466 and 467 of the primary circuit 461. The switching elements 466 and 467 of the primary circuit 461 are preferably normally-off semiconductor apparatuses. The switching elements 468 included in the secondary circuit 462 are common metal insulator semiconductor field effect transistors (MISFETs) composed of silicon,

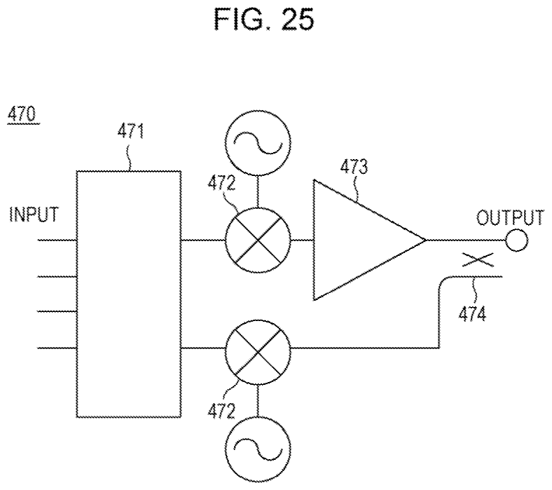

The high-frequency amplifier according to the fifth embodiment is described with reference to FIG. 25. A high-frequency amplifier 470 according to the fifth embodiment may be applied to, for example, a power amplifier used in a mobile phone base station. The high-frequency amplifier 470 includes a digital predistortion circuit 471, mixers 472, a power amplifier 473, and a directional coupler 474. The digital predistortion circuit 471 compensates for nonlinear distortion of an input signal. The mixers 472 mix the input signal the nonlinear distortion of which has been compensated for with an AC signal. The power amplifier 473 amplifies the input signal mixed with the AC signal. In the high-frequency amplifier illustrated in FIG. 25, the power amplifier 473 includes the semiconductor apparatus according to any one of the first to fourth embodiments. The directional coupler 474 is used for, for example, monitoring the input and output signals. The circuit illustrated in FIG. 25 enables the output signal to be mixed with an AC signal in the mixer 472 and then transmitted to the digital predistortion circuit 471 by switching or the like.

Embodiments are described above in detail. The present disclosure is not limited to the above-described specific embodiments. Various modifications and alternations may be made to the present disclosure within the scope of the claims.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor apparatus comprising:
a substrate;
a first semiconductor layer disposed over the substrate, the first semiconductor layer being composed of a nitride semiconductor;
a second semiconductor layer disposed over the first semiconductor layer, the second semiconductor layer being composed of a nitride semiconductor;
an insulating film disposed over the second semiconductor layer;
a source electrode and a drain electrode that are disposed over the second semiconductor layer; and
a gate electrode including
a Schottky region disposed over the second semiconductor layer, and
a gate field-plate region disposed over the insulating film adjacent to the Schottky region,
a first gate electrode section disposed in the gate field-plate region so as to face the drain electrode, and
a second gate electrode section disposed in the Schottky region, and
wherein a material constituting the first gate electrode section has a lower work function than a work function of a material constituting the second gate electrode section.

2. The semiconductor apparatus according to claim 1,
wherein a portion of the second gate electrode section is disposed over the insulating film in the gate field-plate region.

3. The semiconductor apparatus according to claim 1,
wherein the second gate electrode section is disposed over the first gate electrode section in the gate field-plate region.

4. The semiconductor apparatus according to claim 1,
wherein the first gate electrode section is disposed over the second gate electrode section in the gate field-plate region.

5. The semiconductor apparatus according to claim 1,
wherein the material constituting the first gate electrode section has a work function of less than 5.0 eV, and
wherein the material constituting the second gate electrode section has a work function of 5.0 eV or more.

6. The semiconductor apparatus according to claim 1,
wherein the material constituting the first gate electrode section has a work function of 4.5 eV or less, and
wherein the material constituting the second gate electrode section has a work function of 5.0 eV or more.

7. The semiconductor apparatus according to claim 1,
wherein a difference in work function between the material constituting the first gate electrode section and the material constituting the second gate electrode section is 0.5 eV or more,

8. The semiconductor apparatus according to claim 1,
wherein a difference in work function between the material constituting the first gate electrode section and the material constituting the second gate electrode section is 1.0 eV or more.

9. The semiconductor apparatus according to claim 1,
wherein the first gate electrode section is composed of a material including any of Al, Ta, and Ti.

10. The semiconductor apparatus according to claim 1,
wherein the second gate electrode section is composed of a material including any of Pd, Ni, Au, and Pt.

11. The semiconductor apparatus according to claim 1,
wherein the first semiconductor layer is composed of a material including GaN, and
wherein the second semiconductor layer is composed of a material including AlGaN or InAlN.

12. A semiconductor apparatus comprising:
a substrate;
a first semiconductor layer disposed over the substrate, the first semiconductor layer being composed of a nitride semiconductor;
a second semiconductor layer disposed over the first semiconductor layer, the second semiconductor layer being composed of a nitride semiconductor;
an insulating film disposed over the second semiconductor layer;
a source electrode and a drain electrode that are disposed over the second semiconductor layer; and
a gate electrode including
a Schottky region disposed over the second semiconductor layer, and
a gate field-plate region disposed over the insulating film adjacent to the Schottky region,
a first gate electrode section disposed in the gate field-plate region so as to face the drain electrode,
a second gate electrode section disposed in the gate field-plate region so as to be closer to the Schottky region than the first gate electrode section, and
a third gate electrode section disposed in the Schottky region, and
wherein a material constituting the first gate electrode section has a lower work function than a work function of a material constituting the second gate electrode section, and the material constituting the second gate electrode section has a lower work function than a work function of a material constituting the third gate electrode section.

13. The semiconductor apparatus according to claim 12,
wherein the first semiconductor layer is composed of a material including GaN, and
wherein the second semiconductor layer is composed of a material including AlGaN or InAlN.

14. A method for producing a semiconductor apparatus, the method comprising:
forming a first semiconductor layer over a substrate, the first semiconductor layer being composed of a nitride semiconductor;
forming a second semiconductor layer over the first semiconductor layer, the second semiconductor layer being composed of a nitride semiconductor;
forming a source electrode and a drain electrode over the second semiconductor layer;
forming an insulating film over the second semiconductor layer; and
forming an opening in the insulating film and a first gate electrode section such that the first gate electrode section is closer to the drain electrode than the opening, and forming a second gate electrode section over the second semiconductor layer exposed at the opening and over the first gate electrode section,
wherein the first gate electrode section and the second gate electrode section form a gate electrode, and
wherein a material constituting the first gate electrode section has a lower work function than a work function of a material constituting the second gate electrode section.

15. A method for producing a semiconductor apparatus, the method comprising:
forming a first semiconductor layer over a substrate, the first semiconductor layer being composed of a nitride semiconductor;
forming a second semiconductor layer over the first semiconductor layer, the second semiconductor layer being composed of a nitride semiconductor;
forming a source electrode and a drain electrode over the second semiconductor layer;
forming an insulating film over the second semiconductor layer;
forming an opening in the insulating film;
forming a first gate electrode section over the second semiconductor layer exposed at the opening and over a portion of the insulating film which is in the vicinity of the opening; and
forming a second gate electrode section such that the second gate electrode section is closer to the drain electrode than the opening,
wherein the first gate electrode section and the second gate electrode section form a gate electrode, and
wherein a material constituting the second gate electrode section has a lower work function than a work function of a material constituting the first gate electrode section.
